(19) United States
(12) Patent Application Publication
(10) Pub. No.: US 2026/0080940 A1
(43) Pub. Date: Mar. 19, 2026

(54) MEMORY DEVICE

(71) Applicant: Kioxia Corporation, Tokyo (JP)

(72) Inventors: Yuki NAKATA, Yokkaichi Mie (JP); Kouji MATSUO, Ama Aichi (JP)

(73) Assignee: Kioxia Corporation, Tokyo (JP)

(21) Appl. No.: 19/057,236

(22) Filed: Feb. 19, 2025

(30) Foreign Application Priority Data
Sep. 19, 2024 (JP) 2024-162678

(51) Int. Cl. G11C 16/04; G11C 5/06; H10B 43/10; H10B 43/20; H10B 43/35

(52) U.S. Cl. CPC G11C 16/0483; G11C 5/063; H10B 43/10; H10B 43/20; H10B 43/35

(57) ABSTRACT

A first semiconductor extends in a first direction. A first pillar extends in a second direction crossing the first direction and is in contact with the first semiconductor. A first conductor is coupled to an end of the first pillar on a side in the second direction and extends in a third direction crossing the first direction and the second direction. A first transistor is provided farther in the second direction than the first conductor and coupled to the first conductor. A second conductor is provided farther in the second direction than the first conductor, extends in the third direction, and is coupled to the first transistor.

### CROSS-REFERENCE TO RELATED APPLICATIONS

This application is based upon and claims the benefit of priority from Japanese Patent Application No. 2024-162678, filed Sep. 19, 2024, the entire contents of which are incorporated herein by reference.

### FIELD

Embodiments described herein relate generally to a memory device.

### BACKGROUND

There is known a memory device including three-dimensionally arrayed memory cells. To increase the degree of integration of the memory device, the number of constituent elements of the memory device may increase, or the dimensions (length) may excessively be large.

### BRIEF DESCRIPTION OF THE DRAWINGS

FIG. 1 illustrates an example of components and coupling of the components of a memory device of a first embodiment.

FIG. 2 illustrates components and coupling of the components of a single block of the memory device according to the first embodiment.

FIG. 3 illustrates a layout, along the x-y plane, of a part of the memory device according to the first embodiment.

FIG. 4 illustrates a layout, along the x-y plane, of a part of the memory device according to the first embodiment.

FIG. 5 illustrates an example of a sectional structure of a part of the memory device according to the first embodiment.

FIG. 6 illustrates a layout, along the x-y plane, of a part of the memory device according to the first embodiment.

FIG. 7 illustrates an example of the sectional structure of a part of the memory device according to the first embodiment.

FIG. 8 illustrates a layout, along the x-y plane, of a part of the memory device according to the first embodiment.

FIG. 9 illustrates a layout, along the x-y plane, of a part of the memory device according to the first embodiment.

FIG. 10 illustrates a layout, along the x-y plane, of a part of the memory device according to the first embodiment.

FIG. 11 illustrates a layout, along the x-y plane, of a part of the memory device according to the first embodiment.

FIG. 12 illustrates an example of a sectional structure of a part of the memory device according to the first embodiment.

FIG. 13 illustrates components and coupling of the components of a part of a block.

### DETAILED DESCRIPTION

In general, according to one embodiment, a memory device includes a first semiconductor, a first pillar, a first conductor, a first transistor, and a second conductor. The first semiconductor extends in a first direction. The first pillar extends in a second direction crossing the first direction and is in contact with the first semiconductor. The first conductor is coupled to an end of the first pillar on a side in the second direction and extends in a third direction crossing the first direction and the second direction. The first transistor is provided farther in the second direction than the first conductor and coupled to the first conductor. The second conductor is provided farther in the second direction than the first conductor, extends in the third direction, and is coupled to the first transistor.

Embodiments will now be described with reference to the figures. In order to distinguish components having substantially the same function and configuration in an embodiment or over different embodiments from each other, an additional numeral or letter may be added to the end of each reference numeral or letter.

The figures are schematic, and the relation between the thickness and the area of a plane of a layer and the ratio of thicknesses of layers may differ from those in actuality. The figures may include components which differ in relations and/or ratios of dimensions in different figures.

The specification and the claims, when mentioning that a particular (first) component is “coupled” to another (second) component, intend to cover both the form of the first component directly coupled to the second component and the form of the first component coupled to the second component via one or more components which are always or selectively conductive.

Embodiments will be described using a three-dimensional orthogonal coordinate system. A direction of an x axis is referred to as an X direction. A direction opposite to the X direction is referred to as a −X direction. A direction of a y axis is referred to as a Y direction. A direction opposite to the Y direction is referred to as a −Y direction. A direction of a z axis is referred to as a Z direction, and up indicates the Z direction. A direction opposite to the Z direction is referred to as a −Z direction, and down indicates the −Z direction.

### 1. First Embodiment

### 1.1. Configuration (Structure)

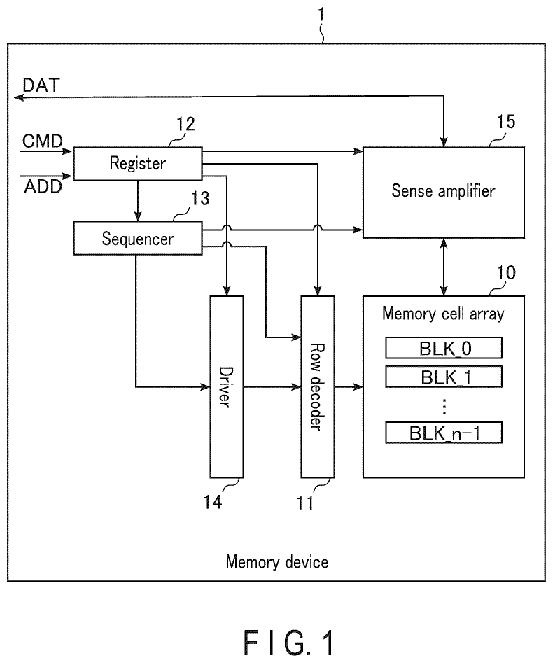

FIG. 1 illustrates an example of components and coupling of the components of a memory device of a first embodiment. A memory device 1 is a device that stores data using memory cells. The memory device is controlled by an external memory controller. The memory device 1 operates based on a command CMD and address information ADD received from outside, or, in one example, a memory controller. The memory device 1 receives data DAT to be written, and outputs data stored in the memory device 1. In one example, the memory device is configured as a single semiconductor chip.

As illustrated in FIG. 1, the memory device 1 includes components such as a memory cell array 10, a row decoder 11, a register 12, a sequencer 13, a driver 14, and a sense amplifier 15.

The memory cell array 10 is a set of memory cell transistors and components coupled to the memory cell transistors. The memory cell array 10 includes a plurality of memory blocks (or blocks) BLK (BLK_0, BLK_1, . . . ). Each block BLK includes a plurality of memory cell transistors MT (not shown). In the memory cell array 10, interconnects such as word lines WL (not shown) and bit lines BL (not shown) are also disposed.

The row decoder 11 is a circuit for selecting a block BLK. The row decoder 11 transfers a voltage supplied from the driver 14 to a single block BLK selected based on a block address received from the register 12.

The register 12 is a circuit that holds the command CMD and the address information ADD received by the memory device 1. The command CMD instructs the sequencer 13 to perform various operations including data read, data write, and data erasure. The address information ADD designates an access target in the memory cell array 10.

The sequencer 13 is a circuit that controls the entire operation of the memory device 1. The sequencer 13 controls the row decoder 11, the driver 14, and the sense amplifier 15 based on the command CMD received from the register 12 to perform various operations including data read, data write, and data erasure.

The driver 14 is a circuit that generates voltages of different magnitudes and applies the generated voltages to some of the components. The driver 14 supplies voltages among the generated voltages selected based on control by the sequencer 13 and the address information ADD to the row decoders 11.

The sense amplifier 15 is a circuit that outputs a signal based on data stored in the memory cell array 10. The sense amplifier 15 senses a state of the memory cell transistors MT, generates read data based on the sensed state, and transfers write data to the memory cell transistors MT.

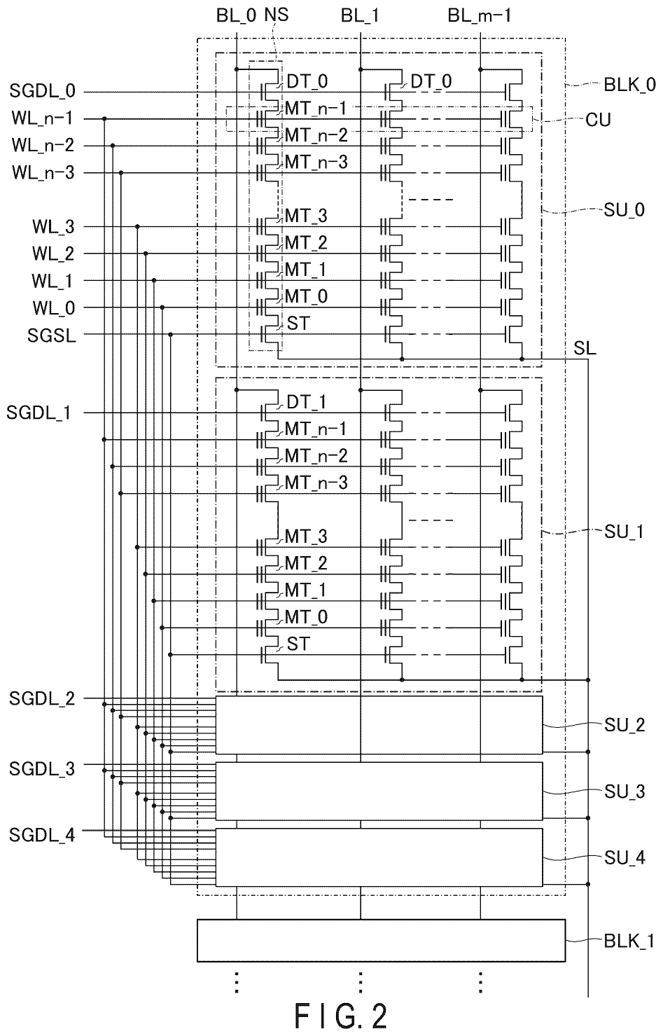

FIG. 2 illustrates components and coupling of the components of a single block of the memory device of the first embodiment. A plurality of blocks BLK, or, in one example, all blocks BLK, include the components and the coupling illustrated in FIG. 2.

A single block BLK includes a plurality of string units SU. FIG. 2 illustrates an example of five string units SU_0 to SU_4.

As illustrated in FIG. 2, each of m bit lines BL_0 to BL_m−1 is coupled, in each block BLK, to a single NAND string NS from each of string units SU_0 to SU_4, where m is a positive integer.

Each NAND string NS includes a single select gate transistor ST, n−1 memory cell transistors MT, and a single select gate transistor DT (DT_0, DT_1, DT_2, DT_3, or DT_4), where n is a positive integer. The memory cell transistor MT is an element that includes a control gate electrode and a charge accumulation film insulated from the surrounding, and stores data in a nonvolatile manner based on charge in the charge accumulation film. The select gate transistors ST, memory cell transistors MT, and select gate transistor DT are coupled in series in the named order between a source line SL and a single bit line BL.

A plurality of NAND strings NS respectively coupled to a plurality of different bit lines BL constitute a single string unit SU. In each string unit SU, the control gate electrodes of the memory cell transistors MT_0 to MT_n−1 are coupled to the word lines WL_0 to WL_n−1, respectively. A set of memory cell transistors MT which share a single word line WL in one string unit SU is referred to as a “cell unit CU”.

The select gate transistors DT_0 to DT_4 belong to the string units SU_0 to SU_4, respectively. In FIG. 2, the select gate transistors DT_2, DT_3, and DT_4 are not illustrated. A gate of the select gate transistor DT_0 of each of the NAND strings NS of the string unit SU_0 is coupled to a select gate line SGDL_0. Similarly, gates of the select gate transistors DT_1, DT_2, DT_3, and DT_4 of the respective NAND strings NS of the string units SU_1, SU_2, SU_3, and SU_4 are coupled to select gate lines SGDL_1, SGDL_2, SGDL_3, and SGDL_4, respectively.

A gate of the select gate transistor ST is coupled to a select gate line SGSL.

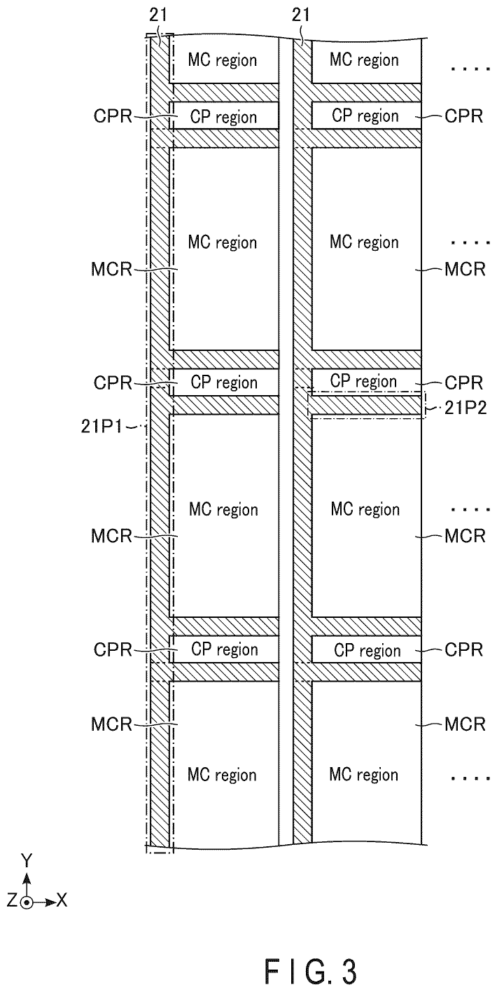

FIG. 3 illustrates a layout, along the x-y plane, of a part of the memory device according to the first embodiment. FIG. 3 shows a structure in a certain layer of the memory device 1. As shown in FIG. 3, the memory device 1 includes a plurality of memory cell regions (or MC regions) MCR, a plurality of CP regions, and a plurality of conductors 21.

The MC region MCR is a region in which the memory cell transistors MT and a structure associated with the memory cell transistors MT are provided. A plurality of MC regions MCR are arranged at intervals in the Y direction to form a column. The plurality of columns of the MC regions MCR are arranged at intervals in the X direction.

The conductor 21 couples certain conductors in the plurality of MC regions MCR. Each conductor 21 includes one first portion 21P1 and a plurality of second portions 21P2. The first portion 21P1 extends in the Y direction. The first portion 21P1 is arranged side by side with one column of the MC regions MCR. The first portion 21P1 is adjacent to one of the two edges, arranged in the X direction, of one column of the MC regions MCR. FIG. 3 shows an example in which the first portion 21P1 is located on the left side of the column of the MC regions MCR.

The second portions 21P2 extend in the X direction and are arranged at intervals in the Y direction. Each second portion 21P2 is located between two MC regions MCR arranged in the Y direction. One second portion 21P2 or two or more second portions 21P2 with an interval are located between two MC regions MCR arranged in the Y direction. FIG. 3 shows an example in which two second portions 21P2 are located. Each second portion 21P2 is coupled to the first portion 21P1 at one of two sides of itself arranged in the X direction. FIG. 3 shows an example in which each second portion 21P2 is coupled to the first portion 21P1 at its left end. In one example, the right end of the second portion 21P2 overlaps the right end of the MC region MCR or is located near the right end of the MC region MCR.

Examples of the conductor 21 include tungsten (W) and titanium nitride (TiN).

CP regions CPR are arranged at intervals in the X direction and the Y direction. Each CP region CPR is located between two MC regions MCR arranged in the Y direction. In one example, each CP region CPR is located between two second portions 21P2 arranged in the Y direction. In one example, the right end of the CP region CPR overlaps the right end of the MC region MCR or is located near the right end of the MC region MCR.

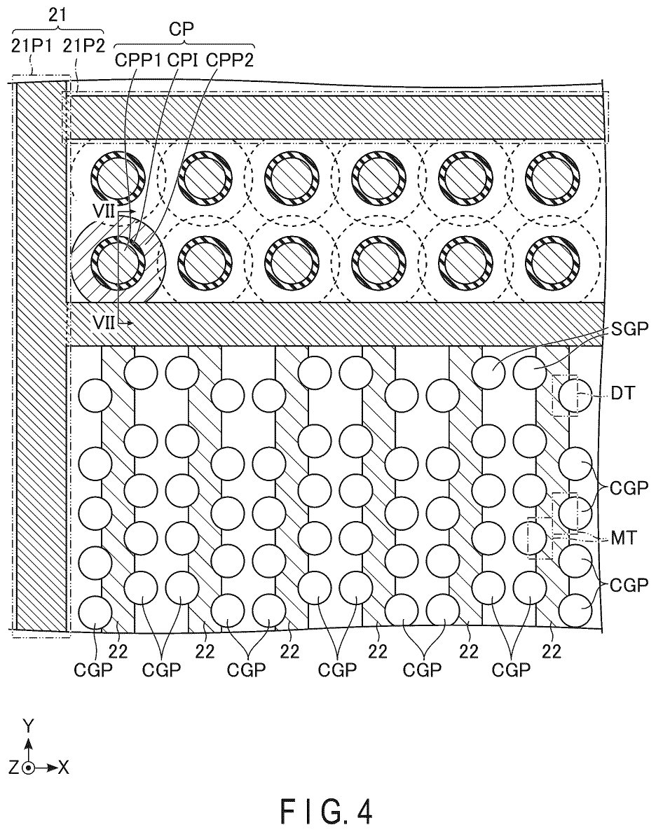

FIG. 4 illustrates a layout, along the x-y plane, of a part of the memory device according to the first embodiment. FIG. 4 shows a layout near the boundary between the MC region MCR and the CP region CPR. FIG. 4 shows one of a plurality of layers arranged in the Z direction.

As shown in FIG. 4, in one layer, each MC region MCR includes a plurality of semiconductors 22, and a plurality of electrode pillars CGP and SGP. Each CP region CPR includes a plurality of contacts CP.

In one example, the semiconductor 22 is silicon (Si) containing an impurity. The impurity includes an element that gives n- or p-type conductivity to the semiconductor 22, and in one example, includes boron (B) or arsenic (As). The semiconductors 22 extend in the Y direction and are arranged at intervals in the X direction. The semiconductor 22 contacts the second portion 21P2 of the conductor 21 on a side in the Y direction. One semiconductor 22 located at an end in the set of a plurality of semiconductors 22 arranged in the X direction faces the conductor 21.

A plurality of sets of one conductor 21 and a plurality of semiconductors 22 shown in FIG. 4 are provided in each of the plurality of layers. That is, the structure including one conductor 21 and a plurality of semiconductors 22 shown in FIG. 4 is repetitively provided in the Z direction.

The electrode pillars CGP are arranged along the x-y plane. In one example, several electrode pillars CGP are arranged in the Y direction to form a column. Two columns of the electrode pillars CGP sandwich one semiconductor 22. The two columns of the electrode pillars CGP sandwiching one semiconductor 22 are located at different positions (coordinates) on the y axis. For this reason, the electrode pillars CGP in one column are not arranged side by side in the X direction with any electrode pillars CGP in the other column. In one example, two adjacent columns of the electrode pillars CGP have a relationship of linear symmetry concerning the y axis. With the above-described arrangement, a certain electrode pillar CGP is arranged in a direction oblique with respect to another electrode pillar CGP. The electrode pillars CGP may be arranged in a matrix.

Each electrode pillar CGP overlaps one semiconductor 22 on a side in the −X direction or on a side in the +X direction, and contacts one semiconductor 22 on the side surface.

Although not illustrated in FIG. 4, each electrode pillar CGP includes an insulator, a conductor, and a semiconductor, as will be described later. Each electrode pillar CGP has a columnar shape and extends in the Z direction. A part of each electrode pillar CGP and a portion of the semiconductor 22 in contact with the electrode pillar CGP, which is in contact with the electrode pillar CGP, function as one memory cell transistor MT.

The electrode pillars SGP are arrayed along the x-y plane. Each electrode pillar SGP is located on the extension line of one column of the electrode pillars CGP. That is, a plurality of electrode pillars CGP and one electrode pillar SGP form one column in the Y direction. Two columns of the electrode pillars CGP and SGP sandwich one semiconductor 22. Two electrode pillars SGP sandwiching one semiconductor 22 are located at different positions (coordinates) on the y axis. For this reason, two (one pair of) electrode pillars SGP sandwiching one semiconductor 22 are not arranged in the X direction. In one example, two adjacent pairs of the electrode pillars SGP have a relationship of linear symmetry concerning the y axis. The electrode pillars CGP and the electrode pillars SGP may be arranged in a matrix.

Each electrode pillar SGP overlaps one semiconductor on a side in the −X direction or on a side in the +X direction, and contacts one semiconductor on the side surface.

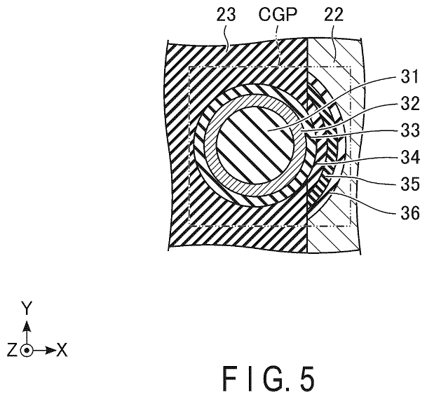

Although not illustrated in FIG. 4, each electrode pillar SGP includes an insulator, a conductor, and a semiconductor, as will be described later with reference to FIG. 5. Each electrode pillar SGP has a columnar shape and extends in the Z direction. A part of each electrode pillar SGP and a portion of the semiconductor 22 in contact with the electrode pillar SGP, which is in contact with the electrode pillar SGP, function as select gate transistor DT.

A region of the MC region MCR, where the semiconductor 22 and the electrode pillars CGP and SGP are not provided, is provided with an insulator 23 (not shown) or buried with the insulator 23. In one example, the insulator 23 includes or is made of silicon oxide.

Each contact CP includes a first portion CPP1, a second portion CPP2, and an insulator CPI. The first portion CPP1 and the second portion CPP2 include a conductor or are made of a conductor. In each contact CP, the first portion CPP1 and the second portion CPP2 overlap, and the first portion CPP1 and the insulator CPI overlap. The second portion CPP2 has a larger area along the x-y plane than the area of the first portion CPP1 along the x-y plane. The first portion CPP1 has a columnar shape extending in the Z direction and is in contact with the second portion CPP2. A plurality of different second portions CPP2 are located in different layers. A side surface of each second portion CPP2 is in contact with a side surface of the second portion 21P2 of the conductor 21 in the layer in which the second portion CPP2 is located. The insulator CPI surrounds a side surface of the second portion CPP2, that is, the outer periphery in FIG. 4.

A region of the CP region CPR, where the contacts CP are not provided, is provided with an insulator. In one example, the insulator includes or is made of silicon oxide.

FIG. 5 illustrates an example of a sectional structure of a part of the memory device according to the first embodiment. FIG. 5 shows an example of a sectional structure of the electrode pillar CGP. As shown in FIG. 5, the electrode pillar CGP includes an insulator 31, a conductor 32, a block insulator 33, a block insulator 34, a charge accumulation film 35, and a tunnel insulator 36.

The insulator 31 has a columnar shape extending in the Z direction. The conductor 32 surrounds a side surface of the insulator 31. In one example, the conductor 32 includes or is made of a metal or a semiconductor containing an impurity. Examples of the metal include tungsten (W) and titanium nitride (TiN). Examples of the semiconductor include silicon. Examples of the impurity include an element that gives n- or p-type conductivity to the semiconductor.

The block insulator 33 surrounds a side surface of the conductor 32. In one example, the block insulator 33 includes or is made of an oxide or nitride of aluminum (Al), hafnium (Hf), titanium (Ti), zirconium (Zr), or lanthanum (La), or silicon oxide or silicon oxynitride (SiON). The block insulator 33 projects to the side of the semiconductor 22 on the side of a surface where the electrode pillar CGP contacts the semiconductor 22.

The block insulator 34 surrounds at least a part of a side surface of the block insulator 33, and is located between the block insulator 33 and one semiconductor 22. The block insulator 34 is located in a region between a plurality of portions of the semiconductor 22. In one example, the block insulator 34 includes or is made of silicon oxide.

The charge accumulation film 35 surrounds a side surface of the block insulator 34, and is located between the block insulator 34 and one semiconductor 22. The charge accumulation film 35 is located in a region between a plurality of portions of the semiconductor 22. The charge accumulation film 35 accumulates (holds) injected charges (electrons). In one example, the charge accumulation film 35 includes or is made of silicon nitride.

The tunnel insulator 36 surrounds a side surface of the charge accumulation film 35, and is located between the charge accumulation film 35 and one semiconductor 22. The tunnel insulator 36 is located in a region between a plurality of portions of the semiconductor 22. The tunnel insulator 36 contacts one semiconductor 22. In one example, the tunnel insulator 36 includes or is made of silicon oxide.

Each electrode pillar CGP in contact with the semiconductor 22 at its left side portion has a structure obtained by reversing, with respect to the y axis, the structure shown in FIG. 5.

The electrode pillar SGP has the same structure as the electrode pillar CGP.

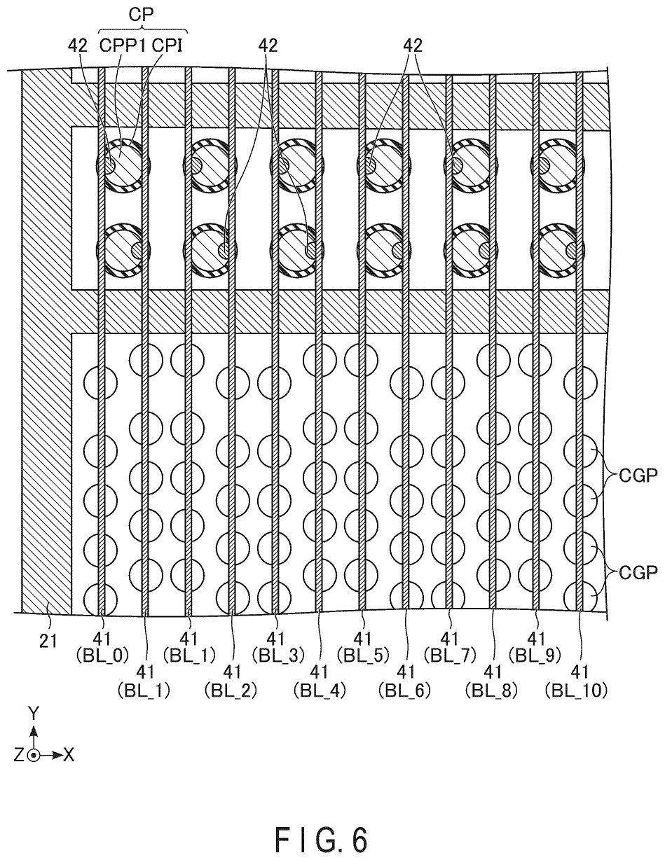

FIG. 6 illustrates a layout, along the x-y plane, of a part of the memory device according to the first embodiment. FIG. 6 illustrates a layout near the boundary between the MC region MCR and the CP region CPR, and shows, concerning the region along the x-y plane, the same region as the region shown in FIG. 4. FIG. 6 shows a region located farther in the Z direction than the region shown in FIG. 4, and the conductor 21 located farthest in the Z direction.

As shown in FIG. 6, the memory device 1 includes a plurality of conductors 41 and a plurality of conductors 42.

The conductors 41 have a linear shape extending in the Y direction and are arranged in the X direction. Examples of the conductor 41 include tungsten and titanium nitride. Each conductor 41 functions as at least a part of one bit line BL. The conductors 41 are arranged in the X direction in ascending order of the identifier (address) of the bit line BL in which the conductor 41 functions as a part thereof. That is, the conductors 41 arranged in the X direction function as at least a part of a bit line BL_0, a bit line BL_1, a bit line BL_2, . . . respectively.

The conductors 42 have a columnar shape and extend in the Z direction. Each conductor 42 overlaps one conductor 41 and one contact CP. The conductor 42 contacts one conductor 41 and the second portion CPP2 of one contact CP.

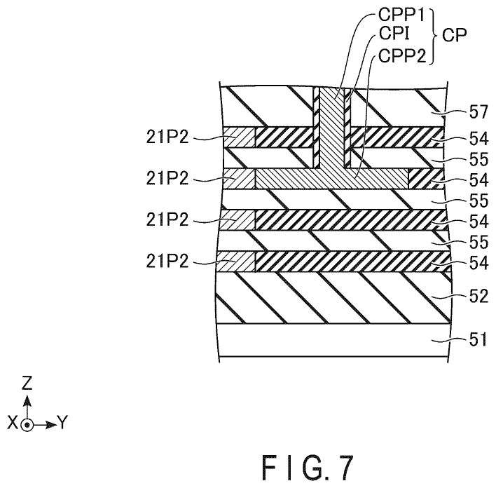

FIG. 7 illustrates a sectional structure of a part of the memory device according to the first embodiment. FIG. 7 shows a structure along a line VII-VII in FIG. 4.

As shown in FIG. 7, the memory device 1 further includes a semiconductor 51, and insulators 52, 54, 55, and 57.

In one example, the semiconductor 51 includes or is made of silicon.

The insulator 52 is located on an upper surface of the semiconductor 51. In one example, the insulator 52 includes or is made of silicon oxide.

The insulators 54 and 55 are alternately located above the upper surface of the semiconductor 51 one by one. The number of insulators 54 equals the number of bit lines BL, that is, m+1. FIG. 7 shows only four insulators 54. In one example, the insulators 54 and 55 include or is made of silicon nitride, silicon oxide, or silicon oxide containing nitrogen. In the layer of each insulator 54, the semiconductor 22 and the second portion 21P2 of the conductor 21 are located.

The insulator 57 is located on an upper surface of the uppermost insulator 54. In one example, the insulator 57 includes or is made of silicon oxide.

Each contact CP includes the second portion CPP2 located in the layer of one insulator 54, and the first portion CPP1 including a lower surface that is in contact with an upper surface of the second portion CPP2. The first portion CPP1 extends through the insulator 57, one or more insulators 54, and one or more insulators 55. Each second portion CPP2 contacts one second portion 21P2 on its side surface. Each contact CP contacts only the second portion 21P2 in the layer in which its lower end is located among the plurality of second portions 21P2 located in a plurality of layers. Each second portion 21P2 may contain a material different from that of remaining portions at a portion including an edge on a side in the Y direction. An example of such a material includes the material of the second portion CPP2 of the contact CP.

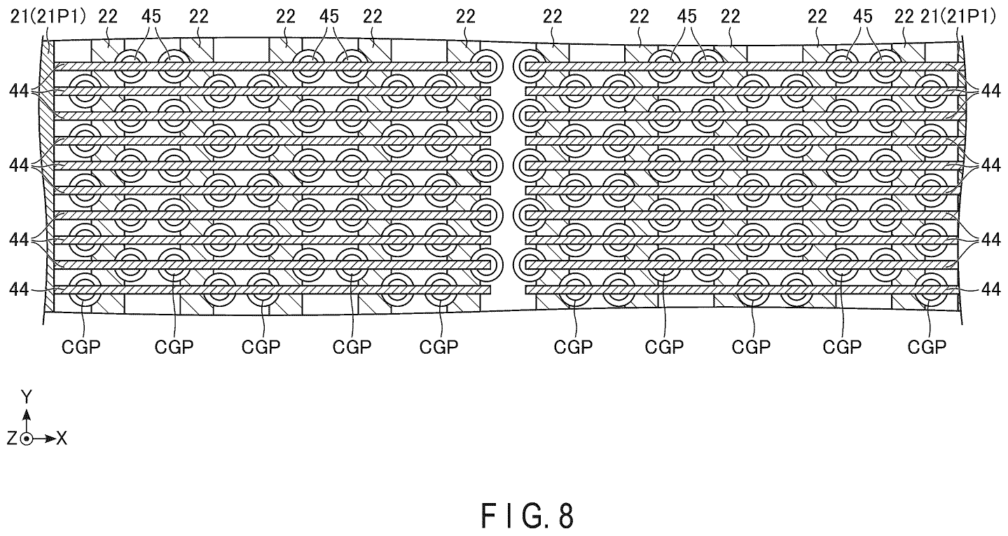

FIG. 8 illustrates a layout, along the x-y plane, of a part of the memory device according to the first embodiment. FIG. 8 illustrates a part of the MC region MCR, and shows a part of a region between the first portions 21P1 of two adjacent conductors 21.

As shown in FIG. 8, the memory device 1 further includes conductors 44 and contacts 45. Each contact 45 overlaps one electrode pillar CGP.

The conductors 44 extend in the X direction and are arranged in the Y direction. Two conductors 44 arranged in the X direction are located between the first portions 21P1 of the two adjacent conductors 21. Hence, a plurality of conductors 44 arranged in the Y direction form one set, and two sets arranged in the X direction are located between the first portions 21P1 of the two adjacent conductors 21.

Each conductor 44 overlaps a plurality of contacts 45 that overlap the plurality of electrode pillars CGP arranged in the X direction, respectively. Each conductor 44 is located farther in the Z direction than the electrode pillar CGP. Each conductor 44 functions as at least a part of one sub-word line SWL.

The interval between the conductors 44 arranged in the X direction may be located at any position. In one example, the interval is located at the center of the set of the electrode pillars CGP arranged in the X direction.

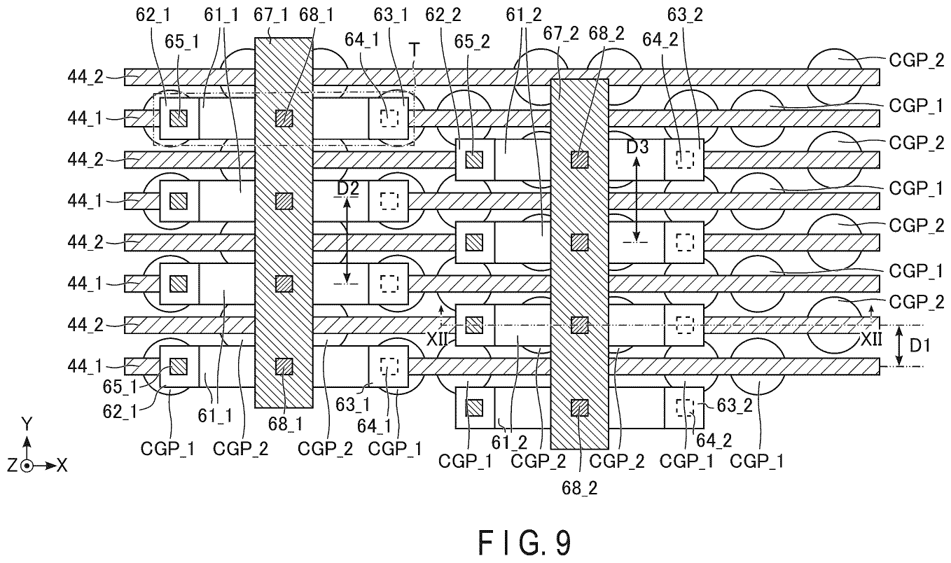

FIG. 9 illustrates a layout, along the x-y plane, of a part of the memory device according to the first embodiment. FIG. 9 illustrates a part of the MC region MCR. As shown in FIG. 9, the memory device 1 further includes semiconductors 61, contacts 64, 65, and 68, and conductors 67. Each of certain electrode pillars CGP arranged in the X direction will be referred to as an electrode pillar CGP_1, and each of other electrode pillars CGP arranged in the X direction will be referred to as an electrode pillar CGP_2 hereinafter. Several electrode pillar CGP_1 are arranged in the Y direction, and several electrode pillar CGP_2 are arranged in the Y direction. On the other hand, the electrode pillar CGP_1 is not arranged side by side in the X direction with any electrode pillar CGP_2 and is located at a different position (coordinates) on the x axis than that of any electrode pillar CGP_2. The sets of the electrode pillars CGP_1 arranged in the X direction and the sets of the electrode pillars CGP_2 arranged in the X direction are alternately arranged in the Y direction one by one. The conductor 44 that overlaps the electrode pillar CGP_1 may be referred to as a conductor 44_1, and the conductor 44 that overlaps the electrode pillar CGP_2 may be referred to as a conductor 44_2.

Semiconductors 61_1 extend in the X direction and are arranged in the Y direction. Each semiconductor 61_1 overlaps one conductor 44_1. The semiconductor 61_1 includes source/drain regions 62_1 and 63_1. The source/drain region 62_1 is located in a region including the end of the semiconductor 61_1 on the side in the −X direction. The source/drain region 63_1 is located in a region including the end of the semiconductor 61_1 on the side in the X direction.

A contact 64_1 overlaps the source/drain region 63_1 and one conductor 44_1. The contact 64_1 contacts the source/drain region 63_1 and one conductor 44_1.

A contact 65_1 overlaps the source/drain region 62_1. The contact 65_1 contacts the source/drain region 62_1.

A conductor 67_1 extends in the Y direction and overlaps a plurality of semiconductors 61_1. The conductor 67_1 is located on a gate insulator (not shown) on the semiconductor 61_1.

Contacts 68_1 are arranged in the Y direction. Each contact 68_1 overlaps one semiconductor 61_1 and the conductor 67_1.

Each semiconductor 61_1, the source/drain regions 62_1 and 63_1 in the semiconductor 61_1, the gate insulator, and a portion of the conductor 67_1 overlapping the semiconductor 61_1 function as one transistor T.

Semiconductors 61_2 extend in the X direction and are arranged in the Y direction. Each semiconductor 61_2 overlaps one conductor 44_2. The semiconductor 61_2 includes source/drain regions 62_2 and 63_2. The source/drain region 62_2 is located in a region including the end of the semiconductor 61_2 on the side in the −X direction. The source/drain region 63_2 is located in a region including the end of the semiconductor 61_2 on the side in the X direction.

A contact 64_2 overlaps the source/drain region 63_2 and one conductor 44_2. The contact 64_2 contacts the source/drain region 63_2 and one conductor 44_2.

A contact 65_2 overlaps the source/drain region 62_2. The contact 65_2 contacts the source/drain region 62_2.

A conductor 67_2 extends in the Y direction and overlaps a plurality of semiconductors 61_2. The conductor 67_2 is located on a gate insulator (not shown) on the semiconductor 61_2.

Contacts 68_2 are arranged in the Y direction. Each contact 68_2 overlaps one semiconductor 61_2 and the conductor 67_2.

Each semiconductor 61_2, the source/drain regions 62_2 and 63_2 in the semiconductor 61_2, the gate insulator, and a portion of the conductor 67_2 overlapping the semiconductor 61_2 function as one transistor T.

As described above, the two types of conductors 44_1 and 44_2 are alternately provided one by one. Based on this, two types of semiconductors 61_1 and 61_2 are provided. When an interval D1 between two conductors 44 arranged in the Y direction is defined as the interval between the center of one conductor 44 on the y axis and the center of the other conductor 44 on the y axis, and an interval D2 between two semiconductors 61_1 arranged in the Y direction is defined as the interval between the center of one semiconductor 61_1 on the y axis and the center of the other semiconductor 61_1 on the y axis, the interval D2 is twice larger than the interval D1. Similarly, when an interval D3 between two semiconductors 61_2 arranged in the Y direction is defined as the interval between the center of one semiconductor 61_2 on the y axis and the center of the other semiconductor 61_2 on the y axis, the interval D3 is twice larger than the interval D2.

If a set of n conductors 44 arranged in the Y direction is repetitively arranged in the Y direction, the interval D2 and the interval D3 are n times larger than the interval D1.

The transistor T coupled to one of two conductors 44 arranged in the X direction may be referred to as a transistor T_0, and the transistor T coupled to the other may be referred to as a transistor T_1 hereinafter. This will be described in more detail.

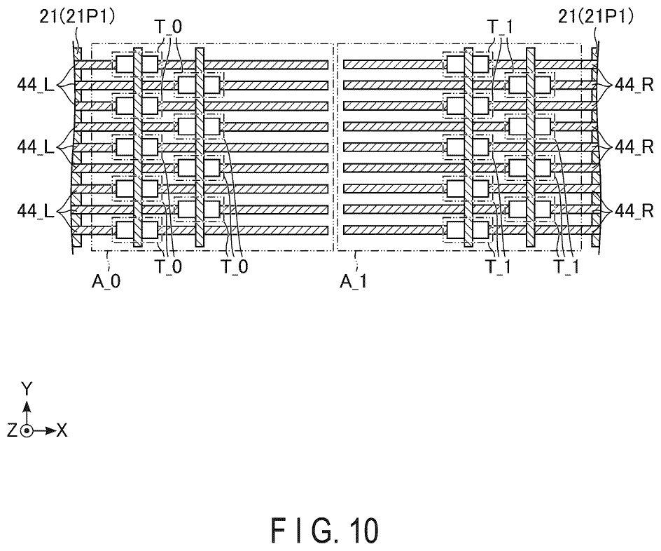

FIG. 10 illustrates a layout, along the x-y plane, of a part of the memory device according to the first embodiment. As shown in FIG. 10, one of two conductors 44 arranged in the X direction (for example, the conductor 44 located farther in the −X direction) will be referred to as a conductor 44_L, and the other of two conductors 44 arranged in the X direction (for example, the conductor 44 located farther in the X direction) will be referred to as a conductor 44_R. A region between the first portions 21P1 of the two conductors 21 arranged in the X direction includes a region A_0 and a region A_1. The regions A_0 and A_1 are arranged in the X direction and do not overlap each other.

The region A_0 includes the conductors 44_L but no conductors 44_R. The region A_0 includes the transistors T_0 but no transistors T_1.

The region A_1 includes the conductors 44_R but no conductors 44_L. The region A_1 includes the transistors T_1 but no transistors T_0.

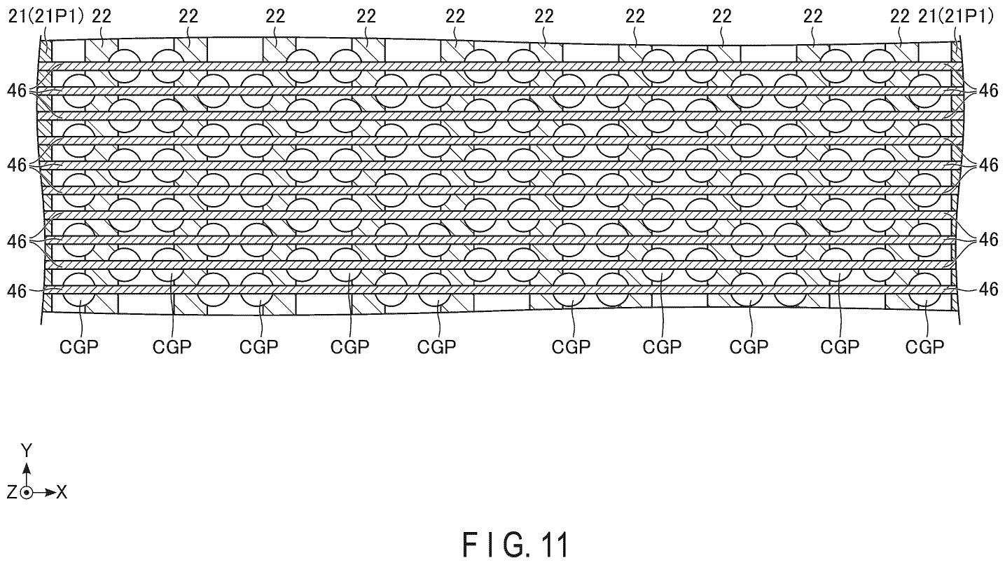

FIG. 11 illustrates a layout, along the x-y plane, of a part of the memory device according to the first embodiment. FIG. 11 illustrates a part of the MC region MCR, and shows, concerning the region along the x-y plane, the same region as the region shown in FIG. 8. FIG. 11 shows a region located farther in the Z direction than the region shown in FIG. 8.

As shown in FIG. 11, the memory device 1 further includes conductors 46. The conductors 46 extend in the X direction and are arranged in the Y direction. Each conductor 46 extends between respective first portions 21P1 of two conductors 21 arranged in the X direction. Each conductor 46 overlaps a set of electrode pillars CGP arranged in the X direction (that is, a set of electrode pillars CGP_1 or a set of electrode pillars CGP_2). Hence, the interval of the conductors 46 along the y axis is the same as the interval D1 of the conductors 44 along the y axis.

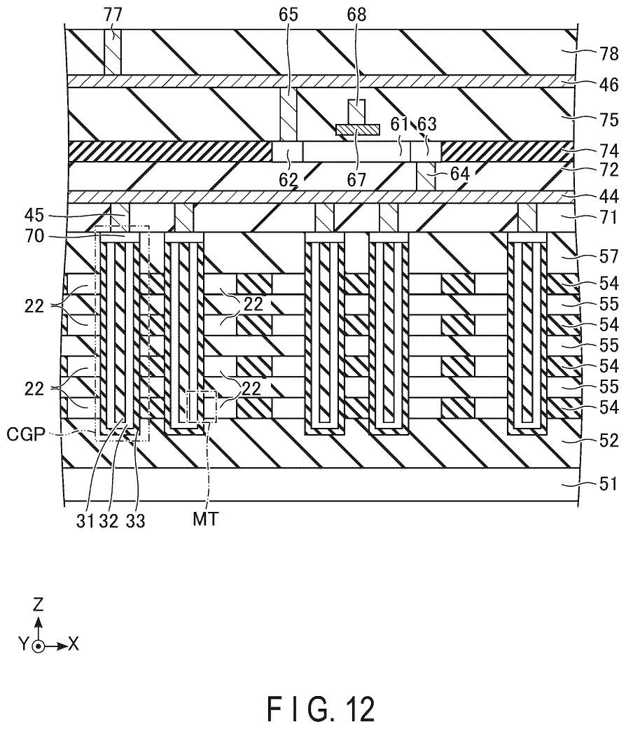

FIG. 12 illustrates an example of a sectional structure of a part of the memory device according to the first embodiment. FIG. 12 shows a structure along a line XII-XII in FIG. 9.

As shown in FIG. 12, the memory device 1 further includes a semiconductor 70, insulators 71, 72, 74, 75, and 78, and a contact 77. In one example, the insulators 71, 72, 74, 75, and 78 include or are made of silicon oxide.

The electrode pillar CGP extends through the insulators 57, 54, and 55 and the semiconductor 22. A lower surface of a part of the electrode pillar CGP is located in the insulator 52. In one example, lower surfaces of the block insulator 33, the conductor 32, and the insulator 31 are located in the insulator 52.

Each semiconductor 70 is located in a region including an upper surface of one electrode pillar CGP. In one example, the semiconductor 70 includes or is made of silicon oxide. The semiconductor 70 is doped with an impurity and has conductivity.

The upper surface of each electrode pillar CGP contacts a lower surface of one contact 45. An upper surface of each contact 45 contacts a lower surface of one conductor 44.

The insulator 71 is located in a region where the contact 45 is not provided in a layer in which the contact 45 is located.

The conductor 44 is located on upper surfaces of the insulators 71 and the contacts 45.

The contact 64 contacts, on its lower surface, an upper surface of the conductor 44.

The insulator 72 is located in a region where the contact 64 is not provided in a layer in which the contact 64 is located.

The source/drain region 63 contacts, on its lower surface, an upper surface of the contact 64.

The insulator 74 is located in a region where the semiconductor 61 is not provided in a layer in which the semiconductor 61 is located.

The conductor 67 is located above an upper surface of the semiconductor 61. A gate insulator is provided between the conductor 67 and the semiconductor 61.

The contact 68 contacts, on its lower surface, an upper surface of the conductor 67.

The contact 65 contacts, on its lower surface, an upper surface of the source/drain region 62.

The insulator 75 is located in a region where the conductor 67 and the contacts 65 and 68 are not provided in a layer in which the conductor 67 and the contacts 65 and 68 are located.

The conductor 46 is located on upper surfaces of the insulator 75 and the contact 65.

The contact 77 contacts, on its lower surface, an upper surface of the conductor 46. In one example, the contact 77 includes or is made of tungsten.

The insulator 78 is located in a region where the contact 77 is not provided in a layer in which the contact 77 is located.

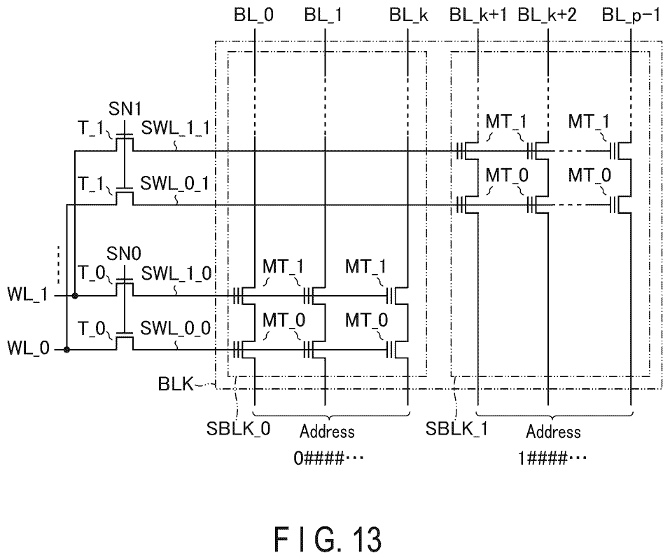

FIG. 13 illustrates block division of the memory device according to the first embodiment, and shows components and coupling of the components of a part of a block. As shown in FIG. 13, each block BLK includes two sub-blocks SBLK (SBLK_0 and SBLK_1). The number of sub-blocks SBLK matches the number of conductors 44 arranged in the X direction between two adjacent conductors 21. The sub-block SBLK_0 includes the bit lines BL_0 to BL_k. k is an integer of 1 or more. k depends on the position of the boundary between the conductors 44 arranged in the X direction. Based on an example in which the boundary is located at the center of a set of electrode pillars CGP arranged in the X direction, k is p/2. p is the number of conductors 44 arranged along the x axis between two adjacent conductors 21. The sub-block SBLK_1 includes bit lines BK_k+1 to BL_p−1.

The word line WL_0 is coupled to a sub-word line SWL_0_0 via the transistor T_0. The sub-word line SWL_0_0 is coupled to the memory cell transistor MT_0 of the sub-block SBLK_0. The transistor T_0 receives a signal SN0 at the gate.

The word line WL_0 is coupled to a sub-word line SWL_0_1 via the transistor T_1. The sub-word line SWL_0_1 is coupled to the memory cell transistor MT_0 of the sub-block SBLK_1. The transistor T_1 receives a signal SN1 at the gate.

The word line WL_1 is coupled to a sub-word line SWL_1_0 via the transistor T_0. The sub-word line SWL_1_0 is coupled to the memory cell transistor MT_1 of the sub-block SBLK_0.

The word line WL_1 is coupled to a sub-word line SWL_1_1 via the transistor T_1. The sub-word line SWL_1_1 is coupled to the memory cell transistor MT_1 of the sub-block SBLK_1.

Similarly, in each case where Q is an integer of 2 or more and n or less, a word line WL_Q is coupled to a sub-word line SWL_Q_0 via the transistor T_0. In each case where Q is an integer of 2 or more and (n−1) or less, the sub-word line SWL_Q_0 is coupled to the memory cell transistor MT_Q of the sub-block SBLK_0.

In each case where Q is an integer of 2 or more and n or less, the word line WL_Q is coupled to a sub-word line SWL_Q_1 via the transistor T_1. In each case where Q is an integer of 2 or more and (n−1) or less, the sub-word line SWL_Q_1 is coupled to the memory cell transistor MT_Q of the sub-block SBLK_1.

The bit lines BL_0 to BL_k have a common value in a specific bit, in one example, the most significant bit of assigned column addresses. In one example, the bit lines BL_0 to BL_k have a value “0” in the most significant bit of assigned column addresses.

The bit lines BL_k+1 to BL_p−1 have a common value in a specific bit, in one example, the most significant bit of assigned column addresses. The bit lines BL_k+1 to BL_p−1 have, in the most significant bit of the column addresses, values different from the value of the most significant bit of the column addresses of the bit lines BL_0 to BL_k. In one example, the bit lines BL_k+1 to BL_p−1 have a value “1” in the most significant bit of the column addresses.

If a column address having a value “0” in the most significant bit is designated as an access target, the signal SN0 has a high level. If a column address having a value “1” in the most significant bit is designated as an access target, the signal SN1 has a high level.

### 1.3. Advantages (Advantageous Effects)

According to the first embodiment, it is possible to provide a memory device which has blocks of a suppressed size and in which conductors can easily be arranged, as described below.

For the purpose of having a large storage capacity, the memory device 1 can include many layers described above with reference to FIG. 4. The larger the number of layers is, the larger the number of contacts CP that need to be arranged is. To double the number of layers in a comparison structure, twice as many contacts CP need to be arranged. To arrange twice as many contacts CP, it can be considered that four contacts CP are provided in the Y direction, whereas two contacts CP are provided in the Y direction in the example shown in FIG. 4. In the example in which two contacts CP are provided in the Y direction, as shown in FIG. 6, the conductors 41 are arranged such that two conductors 41 overlap a column of two contacts CP arranged in the Y direction. However, if four contacts CP are provided in the Y direction, the conductors 41 need to be arranged such that four conductors 41 overlap a column of four contacts CP arranged in the Y direction. This makes arrangement of the conductors 41 difficult.

To address this, it can be considered that, while maintaining the number of contacts CP arranged in the Y direction at two, contacts CP in number larger than the comparison structure are arranged in the X direction to lay twice as many contacts CP as the number of layers in the comparison structure. In this case, the number of electrode pillars CGP coupled to the conductor functioning as one word line WL is twice as many the electrode pillars CGP coupled in the comparison structure. This means that the size of the block BLK is twice larger than the size of the block BLK in the comparison structure. If the block BLK is used as a unit of data erasure, the excessively large size of the block BLK impairs the convenience of the memory device 1.

According to the first embodiment, the memory device 1 includes only two contacts CP in the Y direction in the CP region CPR. For this reason, the conductors 41 each functioning as at least a part of the bit line BL can easily be arranged. Also, the memory device 1 includes the transistor T coupled to the word line WL, and the sub-word line SWL coupled to the transistor T. The conductor 44 functioning as at least a part of the sub-word line SWL is coupled to only the electrode pillars CGP in a smaller number as compared to the conductor 46 functioning as at least a part of the word line WL. Hence, the size of the block BLK is small as compared to a case where the electrode pillars CGP are coupled to the conductor 46.

### 1.4. Modification

The above description is associated with an example in which two conductors 44 are arranged along the x axis between the first portions 21P1 of two conductors 21 arranged along the x axis. However, three or more conductors 44 may be arranged along the x axis between the first portions 21P1 of two conductors 21 arranged along the x axis.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first semiconductor that extends in a first direction;
a first pillar that extends in a second direction crossing the first direction and is in contact with the first semiconductor;
a first conductor that is coupled to an end of the first pillar on a side in the second direction and extends in a third direction crossing the first direction and the second direction;
a first transistor that is provided farther in the second direction than the first conductor and coupled to the first conductor; and
a second conductor that is provided farther in the second direction than the first conductor, extends in the third direction, and is coupled to the first transistor.

2. The device according to claim 1, wherein
the first conductor and the second conductor are arranged in the second direction.

3. The device according to claim 1, wherein
the first conductor is shorter than the second conductor.

4. The device according to claim 1, further comprising:
a second pillar that is in contact with the first semiconductor and is arranged with the first pillar in a fourth direction crossing the first direction, the second direction, and the third direction;
a third conductor that is coupled to an end of the second pillar on a side in the second direction and extends in the third direction;
a second transistor that is provided farther in the second direction than the third conductor and coupled to the third conductor; and
a fourth conductor that is provided farther in the second direction than the third conductor, extends in the third direction, and is coupled to the second transistor.

5. The device according to claim 4, wherein
the first transistor includes a second semiconductor,
the second transistor includes a third semiconductor, and
a sum of a length of the second semiconductor along the third direction and a length of the third semiconductor along the third direction is shorter than a length of the first conductor.

6. The device according to claim 1, further comprising:
a second pillar that is in contact with the first semiconductor, extends in the second direction, and is arranged with the first pillar in the first direction;
a third conductor that is coupled to an end of the second pillar on a side in the second direction and extends in the third direction;
a second transistor that is provided farther in the second direction than the third conductor and coupled to the third conductor; and
a fourth conductor that is provided farther in the second direction than the third conductor, extends in the third direction, and is coupled to the second transistor.

7. The device according to claim 6, wherein
the first conductor and the second conductor are arranged in the second direction, and
the third conductor and the fourth conductor are arranged in the second direction.

8. The device according to claim 7, further comprising:
a fifth conductor that is provided between the first conductor and the third conductor and extends in the third direction,
wherein the first transistor and the second transistor are arranged to be adjacent in the first direction.

9. The device according to claim 8, further comprising:
a sixth conductor,
wherein the first transistor includes a first portion of the sixth conductor, and
the second transistor includes a second portion of the sixth conductor.

10. The device according to claim 1, further comprising:
a third conductor that is arranged with the first conductor in the third direction; and
a second transistor that is provided farther in the second direction than the third conductor and coupled between the third conductor and the second conductor.

11. The device according to claim 1, wherein
the first pillar is in contact with the first semiconductor on a surface facing the third direction or an opposite direction of the third direction.

12. The device according to claim 1, wherein
the device comprises a plurality of first semiconductors including the first semiconductor,
the plurality of first semiconductors extend in the first direction and are arranged at an interval in the second direction, and
the first pillar is in contact with the plurality of first semiconductors.

13. The device according to claim 1, wherein
the first pillar includes a film that holds injected electrons.
